(19) United States
(12) Patent Application Publication
(10) Pub. No.: US 2025/0285858 A1
(43) Pub. Date: Sep. 11, 2025

(54) SINGLE WAFER REACTOR, LOW TEMPERATURE, THERMAL SILICON NITRIDE DEPOSITION

(71) Applicant: Lam Research Corporation, Fremont, CA (US)

(72) Inventors: Aaron Blake Miller, West Linn, OR (US); Jon Henri, West Linn, OR (US); Aaron Durbin, Portland, OR (US); Steven Goza, Beavercreek, OR (US); Easwar Srinivasan, Portland, OR (US); Awnish Gupta, Hillsboro, OR (US); Bart J. Van Schravendijk, Palo Alto, CA (US); Oksana Savchak, Tualatin, OR (US); Fengyan Wei, Lake Oswego, OR (US)

(21) Appl. No.: 18/861,993

(22) PCT Filed: May 25, 2023
(86) PCT No.: PCT/US2023/023633

§ 371 Date: Oct. 31, 2024

Related U.S. Application Data
(60) Provisional application No. 63/365,476, filed on May 27, 2022.

(51) Int. Cl. H01L 21/02; C23C 16/44; C23C 16/455; C23C 16/52

(52) U.S. Cl. CPC H01L 21/0228; C23C 16/4408; C23C 16/45525; C23C 16/45544; C23C 16/52; H01L 21/0217; H01L 21/02211

(57) ABSTRACT

Methods and apparatuses for depositing silicon nitride using a thermal atomic layer deposition process are provided. The temperature of a substrate during deposition is higher than the surround process chamber walls to reduce deposition on the chamber walls, reducing the frequency of chamber cleans.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

Semiconductor device fabrication may involve deposition of silicon nitride films. Silicon nitride thin films have unique physical, chemical, and mechanical properties and thus are used in a variety of applications. For example, silicon nitride films may be used in diffusion barriers, gate insulators, sidewall spacers, encapsulation layers, strained films in transistors, and the like.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Disclosed herein are methods and systems of depositing silicon-containing films. In one aspect of the embodiments herein, a method is provided, the method including: receiving a substrate having features on a pedestal in a process chamber, wherein the process chamber includes one or more chamber walls; and depositing a silicon nitride film on the substrate using a non-plasma atomic layer deposition (ALD) process, wherein the pedestal is a temperature of at least about 400° C. during the non-plasma ALD process, and wherein the chamber walls are less than about 200° C. during the non-plasma ALD process.

In some embodiments, the non-plasma ALD process includes one or more cycles of: flowing a process gas including a silicon-containing precursor into the process chamber; and after flowing the process gas, flowing a nitrogen-containing reactant into the process chamber. In some embodiments, the silicon-containing precursor includes a halogen group-containing silicon precursor. In some embodiments, the silicon-containing precursor includes dichlorosilane (DCS), hexachlorodisilane (HCDS), tetrachlorosilane, or any combination thereof. In some embodiments, the nitrogen-containing reactant includes ammonia (NH₃), hydrazine (N₂H₂), amines bearing carbon, or any combinations thereof. In some embodiments, further including flowing a hydrogen containing gas with the nitrogen-containing reactant. In some embodiments, the non-plasma ALD process further includes introducing a purge gas into the process chamber, wherein introducing the purge gas includes: 1) introducing the purge gas after flowing the silicon-containing precursor; 2) introducing the purge gas after flowing the nitrogen-containing reactant; or both. In some embodiments, a chamber pressure of the process chamber is reduced during the introducing the purge gas into the process chamber. In some embodiments, the purge gas is flowed into the process chamber for a duration between about 0.1 seconds and about 10 seconds. In some embodiments, during the non-plasma ALD process the pedestal temperature is at least about 600° C. In some embodiments, the process chamber further includes one or more thermal shields under the pedestal. In some embodiments, the process chamber further includes a showerhead, and during the non-plasma ALD process a temperature of the showerhead is less than about 170° C. In some embodiments, silicon nitride does not substantially deposit on the chamber walls during the non-plasma ALD process. In some embodiments, chamber pressure during the non-plasma ALD process is between about 5 Torr and about 50 Torr.

In another aspect of the embodiments herein, an apparatus for processing substrates is provided, including: a process chamber having one or more chamber walls and a pedestal; a controller configured to control the process chamber for: receiving a substrate having features on the pedestal in the process chamber; depositing a silicon nitride film on the substrate using a non-plasma atomic layer deposition (ALD) process, wherein the pedestal is a temperature of at least about 400° C. during the non-plasma ALD process, and wherein the chamber walls are less than about 100° C. during the non-plasma ALD process. In some embodiments, the non-plasma ALD process includes one or more cycles of: flowing a process gas including a silicon-containing precursor into the process chamber; and after flowing the process gas, flowing a nitrogen-containing reactant into the process chamber. In some embodiments, the process chamber further includes one or more thermal shields under the pedestal. In some embodiments, silicon nitride does not substantially deposit on the chamber walls during the non-plasma ALD process.

In another aspect of the embodiments herein, an apparatus for processing substrates is provided, including: one or more process chambers, each process chamber including a pedestal; one or more inlet valves into the process chambers and associated flow-control hardware; one or more oxygen filters, one or more moisture filters, or both fluidically connected with the one or more inlet valves; and a controller configured to: flow a silicon-containing precursor gas to the one or more process chambers; flow a nitrogen-containing gas to form silicon nitride.

In some embodiments, the one or more oxygen filters reduce a presence of oxygen below 1 part per billion (ppb) in the silicon-containing precursor gas, nitrogen-containing gas, or both. In some embodiments, the one or more moisture filters reduce a presence of water below 1 part per billion (ppb) in the silicon-containing precursor, nitrogen-containing gas, or both. In some embodiments, the controller is further configured to increase the temperature of the pedestal to at least about 500° C.

In another aspect of the embodiments herein, a method for processing substrates is provided, the method including: receiving a substrate having features on a pedestal in a process chamber, filtering a process gas including a silicon-containing precursor to reduce the presence of at least one of oxygen and water below 1 part per billion; filtering a nitrogen-containing gas to reduce the presence of oxygen, water, or both below 1 part per billion; depositing a silicon nitride film on the substrate using a non-plasma atomic layer deposition (ALD) process, wherein the non-plasma ALD process includes one or more cycles of: flowing the process gas into the process chamber; and after flowing the process gas, flowing a nitrogen-containing reactant into the process chamber. In some embodiments, a temperature of the pedestal is at least about 500° C. during the non-plasma ALD process.

These and other features of the disclosed embodiments will be described in detail below with reference to the associated drawings.

### BRIEF DESCRIPTION OF DRAWINGS

FIG. 1 presents a flow diagram of an operation for one example embodiment.

FIGS. 2-4 present charts of growth rates as functions of temperature, pressure, and dose time.

FIG. 5 presents charts of density, wet etch rate, and stress as functions of refractive index.

FIGS. 6-8 are schematic diagrams of examples of process chambers for performing methods in accordance with disclosed embodiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Semiconductor fabrication processes involve deposition of silicon nitride. Certain fabrication processes may involve forming silicon nitride on and in various structures. Structures may have varying topography and compositions and it may be challenging to deposit silicon nitride into or onto such structures. For example, silicon nitride may be difficult to deposit into high aspect ratio features, and some applications may utilize silicon nitride with variable silicon to nitrogen (Si:N) atomic ratios. While certain methods may be used for depositing silicon nitride generally, such methods have disadvantages such as use of extremely high temperatures, longer process times, reduced tunability windows, and deposition on chamber components that cause more frequent cleans to be performed, reducing throughput.

Provided herein are methods of depositing silicon nitride by thermal atomic layer deposition (ALD) using tunable process conditions during ALD to achieve a variety of advantageous features, including, but not limited to, conformality in high aspect ratio features, reduced chamber deposition, and reduced wafer to wafer variability. In some embodiments, ALD process described herein may be “thermal ALD” processes or “non-plasma ALD” processes, which refer to ALD processes that are performed at elevated temperatures without striking a plasma. While a non-plasma ALD process is described herein, in some embodiments ALD processes described herein may be combined with plasma ALD processes where a plasma is ignited for one or more steps of an ALD process.

Certain disclosed embodiments are capable of depositing highly conformal films. Conformality of films may be measured by step coverage. Step coverage may be defined as a ratio and calculated by comparing the average thickness of a deposited film on a bottom, sidewall, or top of a trench to the average thickness of a deposited film on a bottom, sidewall, or top of a feature or trench. A “feature” of a substrate may be a via or contact hole, which may be characterized by one or more of narrow and/or re-entrant openings, constrictions within the feature, and a high aspect ratio. High aspect ratio may refer to features having an aspect ratio of at least about 10:1 or at least about 15:1 or at least about 20:1 or at least about 50:1 or at least about 100:1 or at least about 150:1 or at least about 200:1. The terms “trench” and “feature” may be used interchangeably in the present disclosure and will be understood to include any hole, via, or recessed region of a substrate.

One example of step coverage may be calculated by dividing the average thickness of the deposited film on the sidewall by the average thickness of the deposited film at the top of the feature and multiplying it by 100 to obtain a percentage. Although ALD can deposit highly conformal films, deposition of films into high aspect ratio features becomes challenging. The step coverage and uniformity of film property along the sidewall depends on, among many factors, the transport of the deposition precursor, reactant ions and/or radicals (such as those generated by igniting a reactant gas with a plasma), and by-products. As the dimension of the trench is reduced, the transport becomes increasing difficult in the trench leading to formation of a seam and/or voids in high aspect ratio trenches.

Certain disclosed embodiments deposit SiN having a conformality of at least about 80% or at least about 90% or at least about 99% or about 100% in high aspect ratio features.

Certain disclosed embodiments are capable of depositing films having superior film properties. For example, SiN deposited using certain disclosed embodiments may exhibit within wafer non-uniformity reduction, stress tuning (such as changing the stress from tensile to compressive), density improvement, and reduced wet etch rate in 100:1 dilute hydrofluoric acid.

Techniques described herein involve thermal atomic layer deposition (ALD). That is, in various embodiments, the reaction between a silane, including an aminosilane or halosilane, and a nitrogen-containing reactant to form silicon nitride is performed without igniting a plasma. ALD is a technique that deposits thin layers of material using sequential self-limiting reactions. Typically, an ALD cycle includes operations to deliver and adsorb at least one reactant to the substrate surface, and then react the adsorbed reactant with one or more reactants to form the partial layer of film. As another example, a silicon nitride deposition cycle may include the following operations: (i) delivery/adsorption of a silicon-containing precursor, (ii) purging of the silicon-containing precursor from the chamber, (iii) delivery of a nitrogen-containing gas, and (iv) purging of the nitrogen-containing gas and other byproducts from the chamber.

Unlike a chemical vapor deposition (CVD) technique, ALD processes use surface mediated deposition reactions to deposit films on a layer-by-layer basis. In one example of an ALD process, a substrate surface that includes a population of surface active sites is exposed to a gas phase distribution of a first precursor, such as a silicon-containing precursor, in a dose provided to a chamber housing a substrate. Molecules of this first precursor are adsorbed onto the substrate surface, including chemisorbed species and/or physiosorbed molecules of the first precursor. It should be understood that when the compound is adsorbed onto the substrate surface as described herein, the adsorbed layer may include the compound as well as derivatives of the compound. For example, an adsorbed layer of a silicon-containing precursor may include the silicon-containing precursor as well as derivatives of the silicon-containing precursor. After a first precursor dose, the chamber is then evacuated to remove most or all of the silicon-containing precursor remaining in gas phase so that mostly or only the adsorbed species remain. In some implementations, the chamber may not be fully evacuated. For example, the chamber may be evacuated such that the partial pressure of the first precursor in gas phase is sufficiently low to mitigate a reaction. A second reactant, such as a nitrogen-containing reactant, is introduced to the chamber so that some of these molecules react with the silicon-containing precursor adsorbed on the surface. In some processes, the second reactant reacts immediately with the adsorbed silicon-containing precursor. The chamber may then be evacuated again to remove unbound nitrogen-containing reactant molecules. As described above, in some embodiments the chamber may not be completely evacuated. Additional ALD cycles may be used to build film thickness.

In certain embodiments, an ALD first precursor dose partially saturates the substrate surface. In some embodiments, the dose phase of an ALD cycle concludes before the precursor contacts the substrate to evenly saturate the surface. Typically, the precursor flow is turned off or diverted at this point, and only purge gas flows. By operating in this sub saturation regime, the ALD process reduces the cycle time and increases throughput. However, because precursor adsorption is not saturation limited, the adsorbed precursor concentration may vary slightly across the substrate surface. Examples of ALD processes operating in the sub-saturation regime are provided in U.S. patent application Ser. No. 14/061,587 (now U.S. Pat. No. 9,355,839), filed Oct. 23, 2013, titled “SUB-SATURATED ATOMIC LAYER DEPOSITION AND CONFORMAL FILM DEPOSITION,” which is incorporated herein by reference in its entirety.

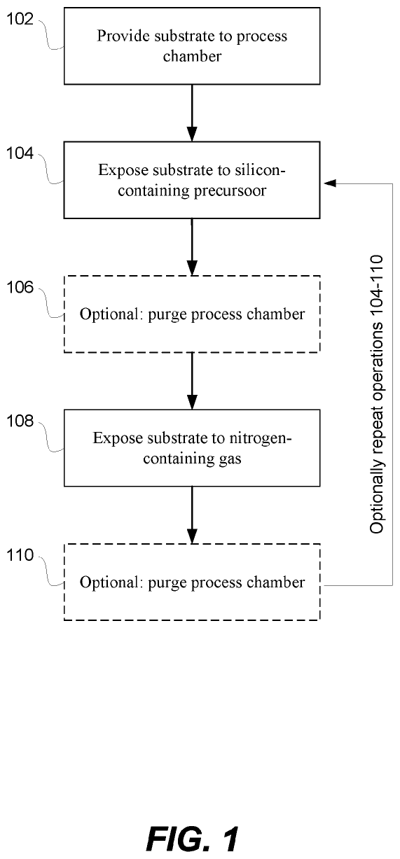

FIG. 1 provides a process flow diagram depicting operations that may be performed in accordance with certain disclosed embodiments.

In operation 102, a substrate is provided to a process chamber. In various embodiments, the process chamber is a single-wafer chamber. In some embodiments, the process chamber is a station within a multi-station chamber. Process conditions described herein are suitable for a single-wafer chamber. The substrate may be a silicon wafer, e.g., a 200-mm wafer, a 300-mm wafer, or a 450 mm wafer, including wafers having one or more layers of material, such as dielectric, conducting, or semi conducting material deposited thereon. Non-limiting examples of under layers include dielectric layers and conducting layers, e.g., silicon oxides, silicon nitrides, silicon carbides, metal oxides, metal nitrides, metal carbides, and metal layers.

The process chamber may be set to a chamber pressure between about 5 mTorr to about 30 Torr, about 0.5 Torr to about 30 Torr, about 0.5 Torr to about 50 Torr. In some embodiments, a higher pressure may be used, e.g., a pressure of at least about 20 Torr, between about 20 Torr and about 30 Torr, or about 20 Torr to about 50 Torr. Such chamber pressures may be used throughout operations 104-110 as described herein. In some embodiments, chamber pressure may be different during different operations. The chamber pressure may also depend on the chemistries selected for various operations described herein.

The substrate may be heated to a substrate temperature between about 25° C. to about 800° C., at least about 400° C., or between about 500° C. to about 700° C., or at least about 650° C. during operations 104-110. It will be understood that substrate temperature as used herein refers to the temperature that the pedestal holding the substrate is set at and that in some embodiments, the substrate when provided to the process chamber on the pedestal may be heated to the desired substrate temperature prior to processing the substrate. The substrate temperature may be the same throughout operations 102-110 as described herein.

In some embodiments, the temperature of the substrate may be much higher than the temperature of the surrounding chamber. In some embodiments, a thermal shield may be placed around the pedestal that thermally insulates the pedestal from the chamber walls and other portions of the process chamber, reducing radiative or convective heat transfer between the pedestal and the chamber walls. In particular, as the temperature of the substrate/pedestal increases from 550° C. to 650° C., radiative heat loss to the surrounding environment may increase by a third or more, increasing power consumption to maintain the higher pedestal temperature and causing the process chamber to heat up. Cooler chamber walls are advantageous as the silicon nitride precursors and reactants may be highly temperature sensitive in regard to deposition, such that a lower temperature of the chamber walls will reduce deposition of silicon nitride on the chamber walls and other chamber components besides the substrate, reducing contamination and allowing for more processing cycles between cleaning operations, both of which are advantageous. In some embodiments, silicon nitride or other compounds derived from reactants introduced into a process chamber do not substantially deposit on the chamber walls during a thermal ALD process. Thus, in some embodiments, while the temperature of the substrate may be at least about 400° C. or at least about 500° C. or at least about 600° C., the chamber walls may be less than about 85° C. or between about 60° C. and about 85° C. In some embodiments, the chamber wall temperature may be less than about 130° C. In some embodiments, the chamber wall temperature may be measured using a probe that is thermally coupled to the exterior of the chamber walls. In some embodiments, the temperature of the interior portion of the chamber wall may be higher than the exterior portion of the chamber wall. Thus, a temperature measured by a probe thermally connected to the exterior of the chamber wall may be, e.g., 85° C. while the interior chamber wall temperature may be higher, e.g., 130° C. for an 85° C. exterior chamber wall temperature measurement.

Similarly, the showerhead temperature may be less than about 200° C., less than about 170° C., about 110° C., or between about 50° C. and about 170° C. even when the pedestal temperature is at least about 400° C., at least about 500° C., or at least about 600° C.

The substrate may be any suitable substrate. The substrate may be a silicon wafer, e.g., a 200-mm wafer, a 300-mm wafer, including wafers having one or more layers of material, such as dielectric, conducting, or semi-conducting material deposited thereon. Non-limiting examples of under layers include dielectric layers and conducting layers, e.g., silicon oxides, silicon nitrides, silicon carbides, metal oxides, metal nitrides, metal carbides, and metal layers. In some embodiments, the substrate includes silicon oxide and silicon. In some embodiments, the substrate includes a partially fabricated 3D-NAND structure.

In some embodiments, the feature(s) may have an aspect ratio of at least about 1:1, at least about 2:1, at least about 4:1, at least about 6:1, at least about 10:1, or at least about 20:1, or at least about 50:1, or at least about 100:1, or at least about 150:1, or at least about 200:1, or higher. The feature(s) may also have a dimension near the opening, e.g., an opening diameter or line width of between about 10 nm to 500 nm, for example between about 25 nm and about 300 nm. Disclosed methods may be performed on substrates with feature(s) having an opening less than about 150 nm. A via, trench or other recessed feature may be referred to as an unfilled feature or a feature. According to various embodiments, the feature profile may narrow gradually and/or include an overhang at the feature opening. A re-entrant profile is one that narrows from the bottom, closed end, or interior of the feature to the feature opening. A re-entrant profile may be generated by asymmetric etching kinetics during patterning and/or the overhang due to non-conformal film step coverage in the previous film deposition, such as deposition of a diffusion barrier. In various examples, the feature may have a width smaller in the opening at the top of the feature than the width of the bottom of the feature. One or more features may have a high aspect ratio, which is defined as having an aspect ratio of greater than about 100:1 or greater than about 150:1 or greater than about 180:1.

In some embodiments, the substrate may be partially fabricated for forming a memory device. In some embodiments, exposed regions of the substrate include silicon-containing surfaces, including but not limited to low-k dielectric material, silicon oxide, silicon nitride, silicon oxynitride, silicon oxycarbide, silicon carbonitride, and silicon carbide. In some embodiments, exposed regions of the substrate include silicon oxynitride.

In operation 104, a silicon-containing precursor may be introduced to the process chamber. Examples of silicon-containing precursors are included elsewhere herein. In some embodiments, the silicon-containing precursor is one or more of the following: dichlorosilane (DCS), hexachlorodisilane (HCDS), tetrachlorosilane, or other chlorosilane precursors.

In some embodiments, the silicon-containing precursor may be flowed at a flow rate of about 100 sccm to about 2000 sccm for a single-wafer chamber. The silicon-containing precursor may be flowed with an inert push gas, such as nitrogen gas or argon gas or a mixture of nitrogen and argon gas. The flow rate of the inert push gas may be about 500 sccm to about 20000 sccm for a single-wafer chamber. Operation 104 may be performed for a duration of about 0.1 second to about 10 seconds. During operation 104, the process chamber may have a chamber pressure of about 5 Torr to about 25 Torr. In some embodiments, additional nitrogen gas may be introduced with the silicon-containing precursor and/or the inert push gas for dilution, for pressure stability, or both. The additional nitrogen gas may be flowed at a flow rate of about 500 sccm to about 20000 sccm for a single-wafer chamber. In one example, dichlorosilane is introduced to a chamber housing the substrate at a flow rate of about 1000 sccm for about 5 seconds at a chamber pressure of about 9.5 Torr in a plasma-free environment.

In operation 106, the process chamber is optionally purged. Operation 106 involves stopping flow of the silicon-containing precursor and introducing flow of an inert gas or a purge gas to remove excess silicon-containing precursor molecules that are not adsorbed onto a surface of the substrate or silicon-containing precursor molecules in a processing region of the process chamber over the substrate in gas phase.

Example inert or purge gases include but are not limited to nitrogen gas and argon. Flow rate of the inert or purge gas during operation 106 is about 1000 sccm to about 40000 sccm for a single-wafer chamber. Introduction of the inert or purge gas may be performed for a duration of about 0.1 second to about 10 seconds. During operation 106, the chamber pressure may be about 0.5 Torr to about 22 Torr. In some embodiments, a lower pressure may be used to purge more effectively. In some embodiments, the chamber pressure during operation 106 is the same as the chamber pressure used during operation 104. In one example, nitrogen gas is introduced at a flow rate of about 10000 sccm for about 10 seconds at a chamber pressure of about 9.5 Torr. The flow rate, duration, and chamber pressure may depend on the precursor used in operation 106.

In operation 108, the substrate is exposed to a nitrogen-containing gas for thermal conversion. The nitrogen-containing gas may be introduced without igniting a plasma. The nitrogen-containing gas may be any suitable nitrogen-containing gas, such as but not limited to nitrogen, ammonia, deuterated ammonia (ND₃), NH₂D, NHD₂, and combinations thereof. In various embodiments, a gas containing both nitrogen and hydrogen may be used. In various embodiments, a mixture of nitrogen-containing gases may be used, such as but not limited to a mixture of nitrogen and ammonia. The nitrogen-containing gas may also be hydrogen-containing. The nitrogen-containing gas may be ammonia (NH₃) gas in various embodiments. The nitrogen-containing gas is introduced at a flow rate of about 100 sccm to about 10000 sccm for a single-wafer chamber.

In some embodiments, a hydrogen-containing gas may also be flowed during operation 108. In some embodiments, the hydrogen-containing gas is hydrogen (H₂) gas. Hydrogen may be flowed at a flow rate of about 0 sccm to about 5000 sccm, or about 100 sccm to about 5000 sccm, for a single-wafer chamber.

In some embodiments, NH₃ is introduced with one or more of a dilution gas, such as nitrogen, or argon, or both. In some embodiments, during exposure to the nitrogen-containing gas without igniting a plasma, nitrogen is flowed at a flow rate of about 500 sccm to about 2000 sccm for a single-wafer chamber as a dilution gas. Argon may be flowed at a flow rate of about 10 slm to about 40 slm for a single-wafer chamber.

Exposure to the nitrogen-containing gas without igniting a plasma may be performed for a duration of about 1 second to about 30 seconds. Exposure to the nitrogen-containing gas may be performed at a chamber pressure of about 5 Torr to about 30 Torr or about 5 Torr to about 50 Torr.

In some embodiments, a higher pressure may be used in operation 108 to improve conformality of the film being deposited.

In one example, NH₃ is introduced at a flow rate of about 4500 sccm for 15 seconds at a chamber pressure of 9.5 Torr. During this operation, the silicon-containing precursor is at least partially converted to silicon nitride such that the nitrogen-containing gas thermally converts adsorbed silicon-containing precursor to silicon nitride.

In operation 110, the chamber is optionally purged. Purging may be performed using any one or more of the process gases and conditions described above with respect to operation 106. In one example, nitrogen gas is flowed at a flow rate of about 10000 sccm for about 10 seconds in a chamber having a chamber pressure of about 9.5 Torr. In some embodiments, purging may be performed at a lower chamber pressure than operations to introduce silicon-containing precursors and/or nitrogen-containing gases into the process chamber.

In some embodiments, operations 104-110 may be performed for multiple cycles to deposit a silicon nitride film to a desired thickness. Each repetition of operations 104-110 may constitute a cycle. Cycles may be repeated until the desired silicon nitride film is deposited.

In some embodiments, forming a silicon-rich silicon nitride film may involve operations 102, 104, 108, 110, and cycles of operations 104-110. In various embodiments, the step coverage of silicon nitride films using certain disclosed embodiments is at least about 80% or at least about 90% or about 100%.

As noted above, in some embodiments, the silicon-containing precursor may be an aminosilane, with hydrogen atoms, such as bisdiethylaminosilane, diisopropylaminosilane (DIPAS), tert-butylamino silane (BTBAS), di-sec-butylaminosilane, or tris(dimethylamino)silane (3DMAS). Aminosilane precursors include, but are not limited to, the following: Hₓ—Si—(NR); where x=1-3, x+y=4 and R is an organic or hydride group.

In some embodiments, a halogen-containing silane may be used such that the silane includes at least one hydrogen atom. Such a silane may have a chemical formula of SiXₐH_{y} where y>1. For example, dichlorosilane (H₂SiCl₂) may be used in some embodiments.

Processes described herein may be used to deposit various films, including silicon-containing films, carbon-containing films, metal films, or other dielectric films. In particular, processes described herein may be used to deposit films where a precursor to be adsorbed onto a surface of a substrate has a pyrolysis temperature below the temperature of a conversion step where the adsorbed precursor is exposed to a reactant. In one instance, the methods can provide a conformal SiN film, which in turn is deposited on a high aspect ratio (HAR) structure. In one embodiment, the aspect ratio (of depth to width) is about 30:1 or greater. After the ALD process, the obtained film can be a conformal film (e.g., having 100% step coverage).

For depositing silicon-containing films, one or more silicon-containing precursors may be used. Silicon-containing precursors suitable for use in accordance with disclosed embodiments include polysilanes (H₃Si—(SiH₂)ₙ—SiH₃), where n≥0. Examples of silanes are silane (SiH₄), disilane (Si₂H₆), and organosilanes such as methylsilane, ethylsilane, isopropylsilane, t-butylsilane, dimethylsilane, diethylsilane, di-t-butylsilane, allylsilane, sec-butylsilane, thexylsilane, isoamylsilane, t-butyldisilane, di-t-butyldisilane, and the like.

A halosilane includes at least one halogen group and may or may not include hydrogens and/or carbon groups. Examples of halosilanes are iodosilanes, bromosilanes, chlorosilanes, and fluorosilanes. Specific chlorosilanes are tetrachlorosilane, trichlorosilane, dichlorosilane, monochlorosilane, chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, thexyldimethylchlorosilane, and the like.

An aminosilane includes at least one nitrogen atom bonded to a silicon atom, but may also contain hydrogens, oxygens, halogens, and carbons. Examples of aminosilanes are mono-, di-, tri- and tetra-aminosilane (H₃Si(NH₂), H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, tert-butylsilanamine, bis(tert-butylamino)silane (SiH₂(NHC(CH₃)₃)₂ (BTBAS), tert-butyl silylcarbamate, SiH(CH₃)—(N(CH₃)₂)₂, SiHCl—(N(CH₃)₂)₂, (Si(CH₃)₂NH)₃ di-isopropylaminosilane (DIPAS), di-sec-butylaminosilane (DSBAS), SiH₂[N(CH₂CH₃)₂]₂ (BDEAS) and the like. A further example of an aminosilane is trisilylamine (N(SiH₃)). In some embodiments, an aminosilane that has two or more amine groups attached to the central Si atom may be used. These may result in less damage than aminosilanes having only a single amine group attached.

Further examples of silicon-containing precursors include trimethylsilane (3MS); ethylsilane; butasilanes; pentasilanes; octasilanes; heptasilane; hexasilane; cyclobutasilane; cycloheptasilane; cyclohexasilane; cyclooctasilane; cyclopentasilane; 1,4-dioxa-2,3,5,6-tetrasilacyclohexane; diethoxymethylsilane (DEMS); diethoxysilane (DES); dimethoxymethylsilane; dimethoxysilane (DMOS); methyl-diethoxysilane (MDES); methyl-dimethoxysilane (MDMS); octamethoxydodecasiloxane (OMODDS); tert-butoxydisilane; tetramethylcyclotetrasiloxane (TMCTS); tetraoxymethylcyclotetrasiloxane (TOMCTS); triethoxysilane (TES); triethoxysiloxane (TRIES); and trimethoxysilane (TMS or TriMOS).

In some implementations silicon-containing precursors may include siloxanes or amino-group-containing siloxanes. In some embodiments, siloxanes used herein may have a formula of X(R¹)ₐSi—O—Si(R²)_{b}Y, where a and b are integers from 0 to 2, and X and Y independently can be H or NR³R⁴, where each of R1, R2, R3 and R4 is hydrogen, unbranched alkyl, branched alkyl, saturated heterocyclic, unsaturated heterocyclic groups, or combinations thereof. In some embodiments, when at least one X or Y is NR³R⁴, R3 and R4, taken together with the atom to which each are attached, form a saturated heterocyclic compound. In some embodiments, the silicon-containing precursors are pentamethylated amino group containing siloxanes or dimethylated amino group containing siloxanes. Examples of amino group containing siloxanes include: 1-diethylamino 1,1,3,3,3,-pentamethyl disiloxane, 1-diisopropylamino-1, 1,3,3,3,-pentamethyl disiloxane, 1 dipropylamino-1,1,3,3,3,-pentamethyl disiloxane, 1-di-n-butylamino-1,1,3,3,3,-pentamethyl disiloxane, 1-di-sec-butylamino-1,1,3,3,3,-pentamethyl disiloxane, 1-N- methylethylamino 1,1,3,3,3,-pentamethyl disiloxane, 1-N-methylpropylamino-1,1,3,3,3,-pentamethyl disiloxane, 1-N-methylbutylamino-1,1,3,3,3,-pentamethyl disiloxane, 1-t-butylamino-1,1,3,3,3,-pentamethyl disiloxane, 1-piperidino-1, 1,3,3,3,-pentamethyl disiloxane, 1-dimethylamino-1,1-dimethyl disiloxane, 1-diethylamino-1, 1-dimethyl disiloxane, 1-diisopropylamino-1,1-dimethyl disiloxane, 1-dipropylamino-1,1-dimethyl disiloxane, 1-di-n-butylamino-1,1-dimethyl disiloxane, 1-di-sec butylamino-1,1-dimethyl disiloxane, 1-N-methylethylamino-1,1-dimethyl disiloxane, 1-N methylpropylamino-1,1-dimethyl disiloxan,e 1-N-methylbutylamino-1,1-dimethyl disiloxane, 1 piperidino-1,1-dimethyl disiloxane, 1-t-butylamino-1,1-dimethyl disiloxane, 1-dimethylamino-disiloxane, 1-diethylamino-disiloxane, 1-diisopropylamino-disiloxane, 1-dipropylamino-disiloxane, 1-di-n-butylamino-disiloxane, 1-di-sec-butylamino-disiloxane, 1-N methylethylamino-disiloxane, 1-N-methylpropylamino-disiloxane, 1-N-methylbutylamino-disiloxane, 1-piperidino-disiloxane, 1-t-butylamino disiloxane, and 1-dimethylamino-1,1,5,5,5,-pentamethyl disiloxane.

Where a deposited film includes oxygen, an oxygen-containing reactant may be used. Examples of oxygen-containing reactants include, but are not limited to, oxygen (O₂), ozone (O₃), nitrous oxide (N₂O), nitric oxide (NO), nitrogen dioxide (NO₂), dinitrogen trioxide (N₂O₃), dinitrogen tetroxide (N₂O₄), dinitrogen pentoxide (N₂O₅), carbon monoxide (CO), carbon dioxide (CO₂), sulfur oxide (SO), sulfur dioxide (SO₂), oxygen-containing hydrocarbons (CₓH_{y}O,_{z}), water (H₂O), formaldehyde (CH₂O), carbonyl sulfide (COS), mixtures thereof, etc.

Where a deposited film includes nitrogen, a nitrogen-containing reactant may be used. A nitrogen-containing reactant contains at least one nitrogen, for example, nitrogen (N₂), ammonia (NH₃), hydrazine (N₂H₄), amines (e.g., amines bearing carbon) such as methylamine (CH₅N), dimethylamine ((CH₃)₂NH), ethylamine (C₂H₅NH₂), isopropylamine (C₃HN), t-butylamine (C₄H₁₁N), di-t-butylamine (C₈H₁₉N), cyclopropylamine (C₃H₅NH₂), sec-butylamine (C₄H₁₁N), cyclobutylamine (C₄H₇NH₂), isoamylamine (C₅H₁₃N), 2-methylbutan-2-amine (C₅H₁₃N), trimethylamine (C₃H₉N), diisopropylamine (C₆H₁₅N), diethylisopropylamine (C₇H₁₇N), di-t-butylhydrazine (C₈H₂ON₂), as well as aromatic containing amines such as anilines, pyridines, and benzylamines. Amines may be primary, secondary, tertiary or quaternary (for example, tetraalkylammonium compounds). A nitrogen-containing reactant can contain heteroatoms other than nitrogen, for example, hydroxylamine, t-butyloxycarbonyl amine and N-t-butyl hydroxylamine are nitrogen-containing reactants. Other examples include NₓO_{y} compounds where x and y≥1, such as nitrous oxide (N₂O), nitric oxide (NO), nitrogen dioxide (NO₂), dinitrogen trioxide (N₂O₃), dinitrogen tetroxide (N₂O₄) and/or dinitrogen pentoxide (N₂O₅).

### Example

The following example is provided to further illustrate aspects of various embodiments. This example is provided to exemplify and more clearly illustrate aspects and is not intended to be limiting.

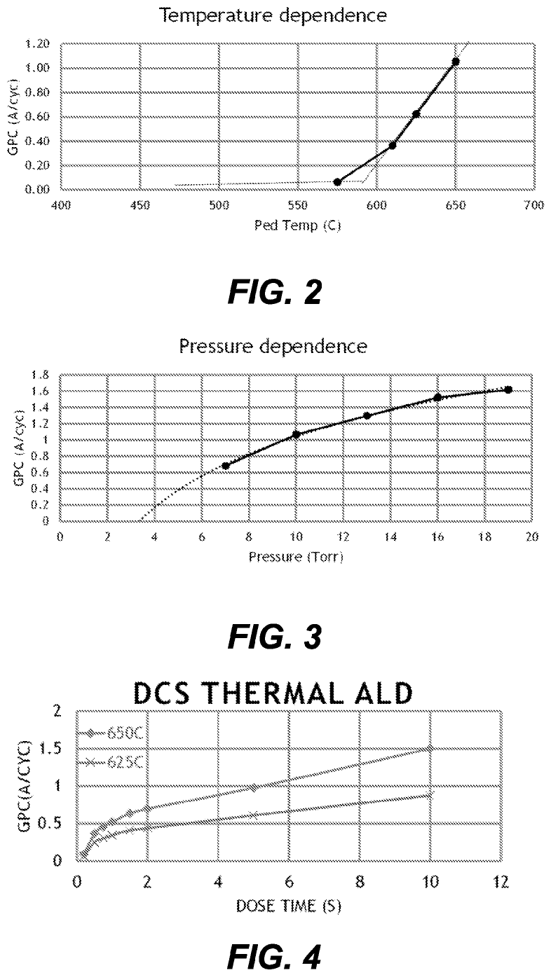

FIG. 2-4 present charts of film growth rate as a function of temperature, pressure, and dose time, respectively. As shown in FIG. 2, higher temperature generally correlates with a higher growth rate per cycle, which is desirable. Notably, deposition may be significantly reduced or potentially not occur at lower temperatures for a thermal ALD process, in particular temperatures less than about 500° C. As the temperature of the pedestal increases above 550° C. the growth rate per cycle increases significantly. FIG. 3 similarly shows that higher pressure correlates with a higher growth rate per cycle, and FIG. 4 shows that a higher dose time for precursor and/or reactant exposure increases growth rate per cycle. Notably, while the dose curves shown in FIG. 4 do not saturate (i.e., do not approach a horizontal line indicating additional dose time would not increase growth or adsorption), the resulting film maintains high conformality. Process parameters for deposition of films represented in FIGS. 2-4 include a pressure of 9.5 Torr, temperature of 650° C., and dose time of 5 seconds, unless otherwise noted.

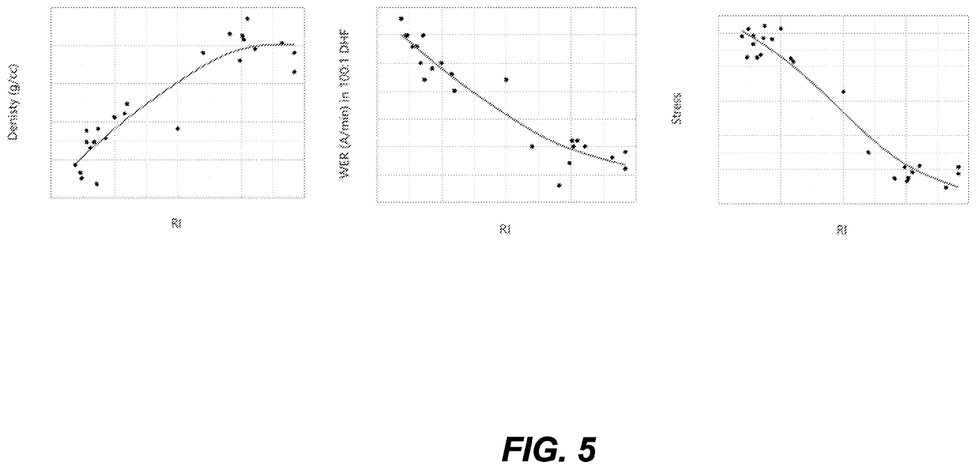

FIG. 5 presents charts of density, wet etch rate, and stress as functions of refractive index. By varying the process parameters as described herein, a silicon nitride film may be deposited that has higher or lower density, a higher or lower wet etch rate (WER), and a higher or lower stress. As the desirable film properties may depend on the particular implementation for the film (as a liner, bulk fill, staircase fill, etc.), being able to deposit a highly conformal film within a large range of film properties is advantageous. In some embodiments, silicon nitride films deposited according to techniques as described herein may have a refractive index between about 2.0 and about 2.25. In some embodiments, silicon nitride films deposited according to techniques as described herein may have a density between about 2.7 and about 2.9 g/cc. In some embodiments, silicon nitride films deposited according to techniques as described herein may have stress between about 600 to 1200 MPa. In some embodiments, silicon nitride films deposited according to techniques as described herein may have a wet etch rate in dilute HF between about 1.5 and about 5 A/min.

### Apparatus

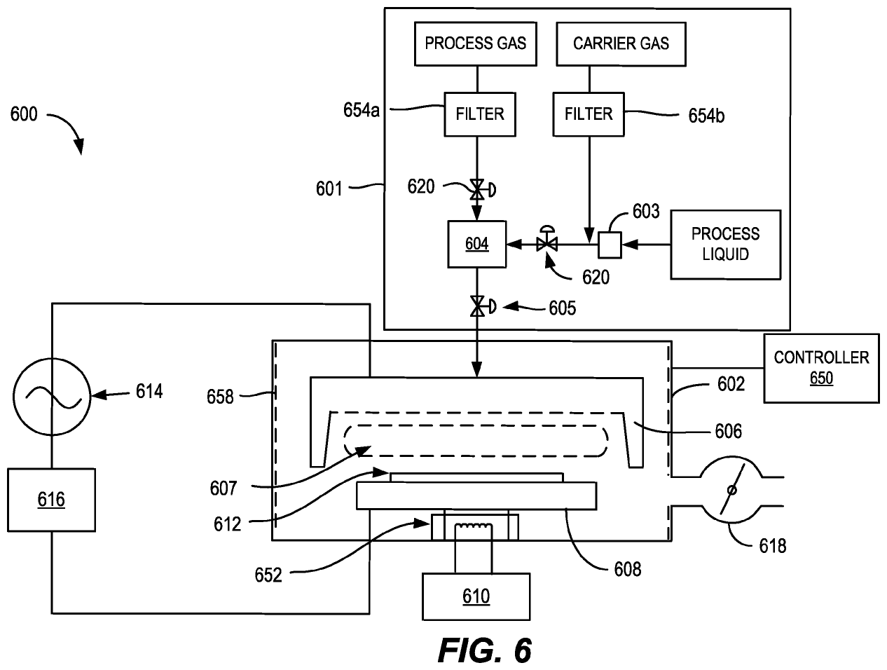

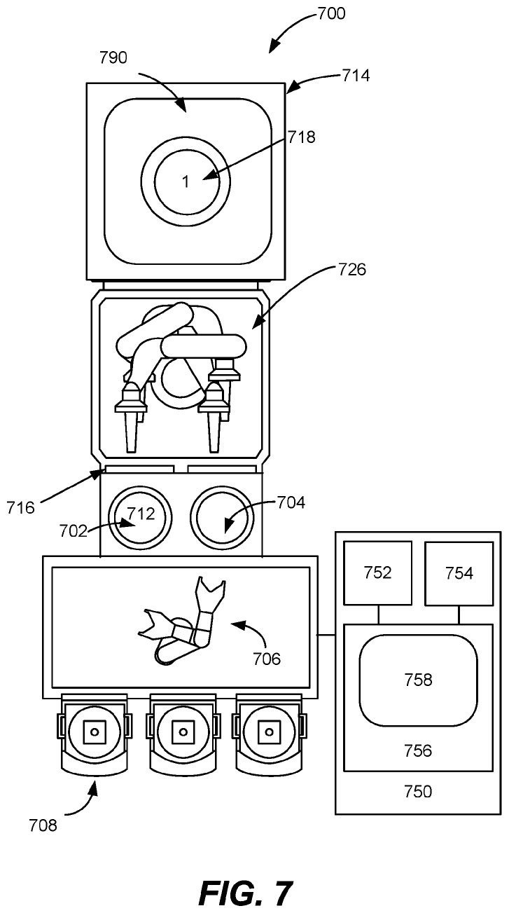

FIG. 6 depicts a schematic illustration of an embodiment of an atomic layer deposition (ALD) process station 600 having a process chamber body 602. In various embodiments, ALD process station 600 may be used for processing substrates. In various embodiments, a single process station 600 is implemented in a tool such as shown in FIG. 7. In some embodiments, a plurality of ALD process stations 600 may be included in a low pressure process tool environment. For example, FIG. 6 depicts an embodiment of a multi-station processing tool 600. In some embodiments, one or more hardware parameters of ALD process station 600 including those discussed in detail below may be adjusted programmatically by one or more computer controllers 650.

ALD process station 600 fluidly communicates with reactant delivery system 601 for delivering process gases to a showerhead 606. Reactant delivery system 601 includes a mixing vessel 604 for blending and/or conditioning process gases, such as a silicon-containing precursor gas, or nitrogen-containing gas, for delivery to showerhead 606. One or more mixing vessel inlet valves 620 may control introduction of process gases to mixing vessel 604. One or more valves 605 may control introduction of gases to the showerhead 606.

As an example, the embodiment of FIG. 6 includes a vaporization point 603 for vaporizing liquid reactant to be supplied to the mixing vessel 604. In some embodiments, vaporization point 603 may be a heated vaporizer. The saturated reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve purging and/or evacuating the delivery piping to remove residual reactant. However, purging the delivery piping may increase process station cycle time, degrading process station throughput. Thus, in some embodiments, delivery piping downstream of vaporization point 603 may be heat traced. In some examples, mixing vessel (not shown) may also be heat traced. In one non-limiting example, piping downstream of vaporization point 603 has an increasing temperature profile extending from approximately 40° C. to approximately 55° C. or from about 60° C. to about 65° C. at mixing vessel. In some embodiments, the mixing vessel may terminate at a showerhead 606. As noted above, the temperature of the showerhead may have an increasing temperature profile up to about 170° C. in some embodiments. In some embodiments, the mixing vessel temperature may similarly increase based on conductive heating from the showerhead.

In some embodiments, liquid precursor or liquid reactant may be vaporized at a liquid injector. For example, a liquid injector may inject pulses of a liquid reactant into a carrier gas stream upstream of the mixing vessel. In one embodiment, a liquid injector may vaporize the reactant by flashing the liquid from a higher pressure to a lower pressure. In another example, a liquid injector may atomize the liquid into dispersed microdroplets that are subsequently vaporized in a heated delivery pipe. Smaller droplets may vaporize faster than larger droplets, reducing a delay between liquid injection and complete vaporization. Faster vaporization may reduce a length of piping downstream from vaporization point 603. In one scenario, a liquid injector may be mounted directly to mixing vessel. In another scenario, a liquid injector may be mounted directly to showerhead 606.

In some embodiments, a liquid flow controller (LFC) upstream of vaporization point 603 may be provided for controlling a mass flow of liquid for vaporization and delivery to ALD process station 600. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, this may be performed by disabling a sense tube of the LFC and the PID controller.

In some embodiments, one or more filters 654a and 654b may be present in reactant delivery system 601. In some embodiments, the filters may be filters for oxygen and/or water vapor. In some embodiments, there may be more than one filter for each gas, e.g., an oxygen filter and a moisture filter. Oxygen and water vapor may contribute to defects in a silicon nitride deposition system. In some embodiments, oxygen and/or water vapor may react with halogen-containing precursors, causing corrosion of the showerhead and other chamber components, which may in turn increase the presence of defects in deposited films. Additionally, silicon nitride will oxidize in the presence of oxygen, thus contaminants in the process gases, even in small amounts, may contribute to silicon oxide formation or add oxygen impurities, which is undesirable. While process chambers and tools are typically provided various process and carrier gases from pipes within a fabrication facility, in some embodiments such gases may have significant enough amounts of oxygen and/or moisture to cause defects, e.g., corrosion of the showerhead, silicon dioxide formation in a silicon nitride film, or oxygen impurities in a silicon nitride film. Thus, to reduce the presence of oxygen and/or moisture in the gases flowed into the process chamber, one or more filters may be placed upstream of mixing vessel 604. While filters 654a and 654b are shown upstream of valves 620, the precise location of the filters may vary. In various embodiments, filters 654a and 654b are fluidically connected to one or more of inlet valves 620 which may control introduction of, e.g., silicon-containing precursor gas, nitrogen-containing gas, and/or purge gas into mixing vessel 604. Thus, in some embodiments, methods described herein may include filtering a silicon-containing precursor gas, nitrogen-containing gas, and/or purge gas during an ALD process as such respective gases are flowed into a process chamber. It is to be understood that the phrase “fluidically connected” may be used herein to describe connections between two or more components that place such components in fluidic communication with one another. In some embodiments, such filters may reduce the presence of oxygen and/or moisture in process gases to less than about 1 part per billion.

Showerhead 606 distributes process gases toward substrate 612. In the embodiment shown in FIG. 6, the substrate 612 is located beneath showerhead 606 and is shown resting on a pedestal 608. Showerhead 606 may have any suitable shape, and may have any suitable number and arrangement of ports for distributing process gases to substrate 612.

In some embodiments, pedestal 608 may be raised or lowered to expose substrate 612 to a volume between the substrate 612 and the showerhead 606. It will be appreciated that, in some embodiments, pedestal height may be adjusted programmatically by a suitable computer controller 650.

In another scenario, adjusting a height of pedestal 608 may allow a plasma density to be varied during plasma activation in the process in embodiments where a plasma is ignited. At the conclusion of the process phase, pedestal 608 may be lowered during another substrate transfer phase to allow removal of substrate 612 from pedestal 608.

In some embodiments, pedestal 608 may be temperature controlled via heater 610. In some embodiments, the pedestal 608 may be heated to a temperature of about 25° C. to about 800° C., or about 200° C. to about 700° C., during deposition of silicon nitride films as described in disclosed embodiments. In some embodiments, the pedestal is set at a temperature of about 45° C. to about 800° C., or about 500° C. to about 700° C. In some embodiments, the same pedestal 608 is used for multiple operations in accordance with certain disclosed embodiments.

In some embodiments, the pedestal 608 may have a thermal shield 652 positioned under it that reduces unwanted radiative heat loss from the pedestal and reduce radiative heat transfer to other components within the processing chamber. The thermal shield 652 may be part of or connected to a thermal collar that extends around the pedestal's support column and blocks radiative heat transfer from the pedestal to chamber walls 658 (as shown by the dashed lines). The thermal shield may have a composition of a thermally insulative material, such as ceramic. An appropriate apparatus for thermal shields as disclosed herein is further discussed and described in U.S. Patent Application No. 63/202, 154, filed May 28, 2021, and titled “APPARATUSES FOR THERMAL MANAGEMENT OF A PEDESTAL AND CHAMBER” which is incorporated herein in its entireties.

In some embodiments, the thermal shield may protect the chamber wall and showerhead such that even if the pedestal is at a temperature greater than about 500° C. or about 600° C., the chamber wall and showerhead may have a temperature less than about 200° C. In some embodiments, while the temperature of the substrate may be at least about 500° C. or at least about 600° C., the chamber walls may be less than about 85° C. or between about 60° C. and about 85° C. Similarly, the showerhead may be less than about 170° C., about 110° C., or between about 90° C. and about 170° C. even when the pedestal temperature is at least about 500° C. or at least about 600° C.

Further, in some embodiments, pressure control for ALD process station 600 may be provided by butterfly valve 618. As shown in the embodiment of FIG. 6, butterfly valve 618 throttles a vacuum provided by a downstream vacuum pump (not shown). However, in some embodiments, pressure control of ALD process station 600 may also be adjusted by varying a flow rate of one or more gases introduced to the ALD process station 600.

In some embodiments, a position of showerhead 606 may be adjusted relative to pedestal 608 to vary a volume between the substrate 612 and the showerhead 606. Further, it will be appreciated that a vertical position of pedestal 608 and/or showerhead 606 may be varied by any suitable mechanism within the scope of the present disclosure. In some embodiments, pedestal 608 may include a rotational axis for rotating an orientation of substrate 612. It will be appreciated that, in some embodiments, one or more of these example adjustments may be performed programmatically by one or more suitable computer controllers 650.

In some embodiments, instructions for a controller 650 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, a first recipe phase may include instructions for setting a flow rate of a silicon-containing precursor gas, instructions for setting a flow rate of a carrier gas (such as argon), and time delay instructions for the first recipe phase. A second recipe phase may include modulating or stopping a flow rate of an inert and/or a reactant gas, instructions for optionally heating, instructions for setting a flow rate of a carrier gas (such as argon), and time delay instructions for a second recipe phase. A third, subsequent recipe phase may include instructions for modulating or stopping a flow rate of an inert and/or a reactant gas, and instructions for modulating a flow rate of a nitrogen-containing gas and time delay instructions for the third recipe phase. A fourth recipe phase may include instructions for modulating or stopping a flow rate of an inert and/or a reactant gas, instructions for modulating the flow rate of a carrier or purge gas, and time delay instructions for the fourth recipe phase. A fifth, subsequent recipe phase may include instructions for setting a flow rate of a nitrogen-containing gas, instructions for igniting a plasma, and instructions for modulating a flow rate of a carrier or purge gas and time delay instructions for the fifth recipe phase. A sixth recipe phase may include instructions for modulating or stopping a flow rate of an inert and/or a reactant gas, instructions for modulating the flow rate of a carrier or purge gas, and time delay instructions for the sixth recipe phase. It will be appreciated that these recipe phases may be further subdivided and/or iterated in any suitable way within the scope of the disclosed embodiments. In some embodiments, the controller 650 may include any of the features described below with respect to system controller 750 of FIG. 7 and system controller 650 of FIG. 6.

A process station may be included in a single-station chamber or single-chamber tool such as shown in FIG. 7. FIG. 7 depicts an example processing apparatus according to disclosed embodiments. Tool 700 includes a processing chamber 714 which includes a processing station 790 may process a wafer. The processing chamber 714 is configured to deposit silicon oxide, deposit silicon nitride, anneal substrates using thermal or plasma anneals, and the like.

Tool 700 also includes a wafer transfer unit configured to transport wafers within the tool 700. Additional features of tool 700 will be discussed in greater detail below, and various features are discussed here with respect to some of the described techniques. In the depicted illustration, the wafer transfer unit includes a first robotic arm unit 726 in a first wafer transfer module and a second robotic arm unit 706 in a second wafer transfer module that may be considered an equipment front end module (EFEM) configured to received containers for wafers, such as a front opening unified module (FOUP) 708. The first robotic arm unit 726 is configured to transport a wafer between the processing chamber 714 and the second robotic arm unit via module 704 which may hold multiple wafers such as shown in module 702 with substrate 712. The second robotic arm unit 706 is configured to transport the wafer between a FOUP and module 704, or from module 702 to FOUP. After a wafer has been prepared in the module 704, the wafer transfer unit is able to transfer the wafer to first processing chamber 714 for deposition and optional anneal in situ.

Similar to above, the first wafer transfer module may a vacuum transfer module (VTM). Airlock or module 704, also known as a loadlock, is shown and may be individually optimized to perform various fabrication processes. The tool 700 also includes a FOUP 708 that is configured to lower the pressure of the tool 700 to a vacuum or low pressure, e.g., between about 1 mTorr and about 10 Torr, and maintain the tool 700 at this pressure. This includes maintaining the processing chamber 714, and the first wafer transfer module at the vacuum or low pressure. The second wafer transfer module may be at a different pressure, such as atmospheric. As the wafer is transferred throughout the tool 700, it is therefore maintained at the vacuum or low pressure.

In a further example, a substrate is placed in one of the FOUPs 708 and the second robot arm unit 706, or front-end robot, transfers the substrate from the FOUP 718 to an aligner, which allows the substrate to be properly centered before it is etched, or deposited upon, or otherwise processed. After being aligned, the substrate is moved by the second robot arm unit 706 into the airlock module 704. Because airlock modules have the ability to match the environment between an ATM and a VTM, the substrate is able to move between the two pressure environments without being damaged. From the airlock module 704, the substrate is moved by the first robot arm unit 726 through the first wafer transfer module, or VTM, and into the processing chamber 714. In order to achieve this substrate movement, the first robot arm unit 726 uses end effectors on each of its arms.

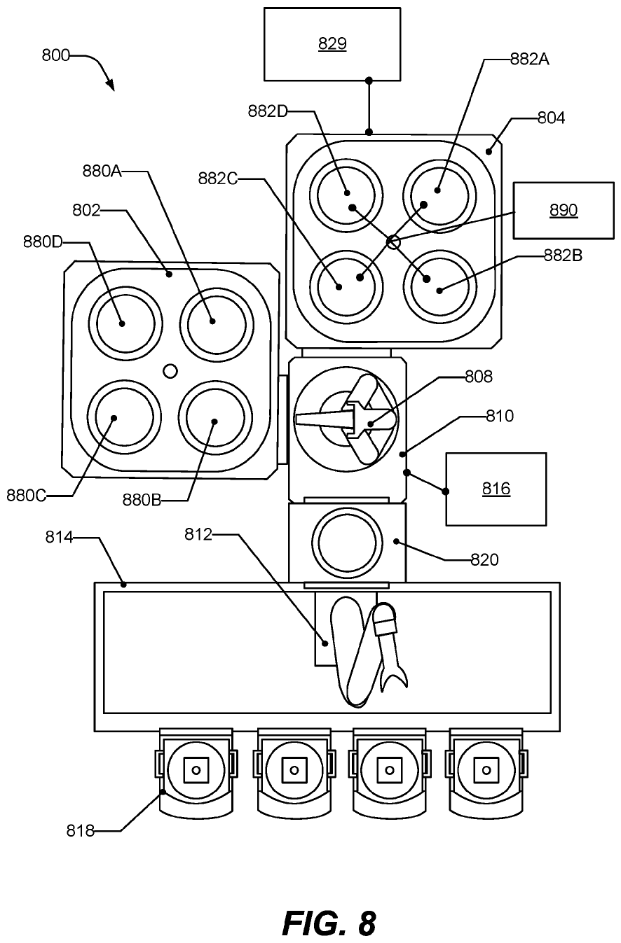

FIG. 7 also depicts an embodiment of a system controller 750 employed to control process conditions and hardware states of process tool 700. System controller 750 may include one or more memory devices 756, one or more mass storage devices 754, and one or more processors 752. Processor 752 may include a CPU or computer, analog and/or digital input/output connections, stepper motor controller boards, etc. In some embodiments, system controller 750 includes machine-readable instructions for performing operations such as those described above with respect to FIG. 8 and below with respect to FIG. 8.

As described above, one or more process stations may be included in a multi-station processing tool. FIG. 8 depicts an example processing apparatus according to disclosed embodiments. Tool 800 includes a first processing chamber 802 and a second processing chamber 804. The first processing chamber 802 includes a plurality of processing stations, four stations 880A-D, that each may process a wafer. The first processing chamber 802 is configured to perform plasma treatment operations on the wafers. The second processing chamber 804 is configured to perform deposition on the wafer and may be considered a deposition chamber. The second processing chamber 804 also includes a plurality of processing stations, four stations 882A-D, that each may process a wafer. The first and second processing chambers 802 and 804 may be considered multi-station processing chambers.

Tool 800 also includes a wafer transfer unit configured to transport one or more wafers within the tool 800. Additional features of tool 800 will be discussed in greater detail below, and various features are discussed here with respect to some of the described techniques. In the depicted illustration, the wafer transfer unit includes a first robotic arm unit 808 in a first wafer transfer module 810 and a second robotic arm unit 812 in a second wafer transfer module 814 that may be considered an equipment front end module (EFEM) configured to received containers for wafers, such as a front opening unified module (FOUP) 816. The first robotic arm unit 808 is configured to transport a wafer between the first processing chamber 802 and the second processing chamber 804, and between the second the second robotic arm unit 812. The second robotic arm unit 812 is configured to transport the wafer between a FOUP and the first robotic arm unit 808. After a wafer has been treated in the first processing chamber 802, the wafer transfer unit is able to transfer the wafer from the first processing chamber 802, to the second processing chamber 804 where one or more layers of encapsulation material may be deposited on one or more wafers.

Similar to above, the first wafer transfer module 810 may a vacuum transfer module (VTM). Airlock 820, also known as a loadlock or transfer module, is shown and may be individually optimized to perform various fabrication processes. The tool 800 also includes a FOUP 816 that is configured to lower the pressure of the tool 800 to a vacuum or low pressure, e.g., between about 1 mTorr and about 10 Torr, and maintain the tool 800 at this pressure. This includes maintaining the first and second processing chambers 802 and 804, and the first wafer transfer module 810 at the vacuum or low pressure. The second wafer transfer module 814 may be at a different pressure, such as atmospheric. As the wafer is transferred throughout the tool 800, it is therefore maintained at the vacuum or low pressure. For example, as the wafer is transferred from the first processing chamber 802, into the first wafer transfer module 810, and to the second processing chamber 804, the wafer is maintained at the vacuum or low pressure and not exposed to atmospheric pressure.

In a further example, a substrate is placed in one of the FOUPs 818 and the second robot arm unit 812, or front-end robot, transfers the substrate from the FOUP 818 to an aligner, which allows the substrate to be properly centered before it is etched, or deposited upon, or otherwise processed. After being aligned, the substrate is moved by the second robot arm unit 812 into the airlock 820. Because airlock modules have the ability to match the environment between an ATM and a VTM, the substrate is able to move between the two pressure environments without being damaged. From the airlock 820, the substrate is moved by the first robot arm unit 808 through the first wafer transfer module 810, or VTM 810, and into the first processing chamber 802. In order to achieve this substrate movement, the first robot arm unit 808 uses end effectors on each of its arms.

FIG. 8 also depicts an embodiment of a system controller 829 employed to control process conditions and hardware states of tool 800. System controller 829 may include one or more memory devices (not shown), one or more mass storage devices (not shown), and one or more processors (not shown). Processors may include a CPU or computer, analog, and/or digital input/output connections, stepper motor controller boards, etc.

In some embodiments, system controller 829 controls all of the activities of tool 800. System controller 829 executes system control software stored in mass storage device, loaded into memory device, and executed on processor. Alternatively, the control logic may be hard coded in the system controller 829. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software may include instructions for controlling the timing, mixture of gases, gas flow rates, chamber and/or station pressure, chamber and/or station temperature, wafer temperature, target power levels, RF power levels, substrate pedestal, chuck and/or susceptor position, and parameters of a particular process performed by tool 800. System control software may be configured in any suitable way. For example, various process tool component subroutines or control objects may be written to control operation of the process tool components used to carry out various process tool processes. System control software may be coded in any suitable computer readable programming language.

In some embodiments, system control software may include input/output control (IOC) sequencing instructions for controlling the various parameters described above. Other computer software and/or programs stored on mass storage device and/or memory device associated with system controller 829 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal and to control the spacing between the substrate and other parts of tool 800.

A process gas control program may include code for controlling gas composition (e.g., silicon-containing precursor gases, nitrogen-containing gases, carrier gases, inert gases, and/or purge gases as described herein) and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. Alternatively, the heater control program may control delivery of a heat transfer gas (such as helium or nitrogen) to the substrate.

A plasma control program may include code for setting RF power levels applied to the process electrodes in one or more process stations in accordance with the embodiments herein.

A pressure control program may include code for maintaining the pressure in the reaction chamber in accordance with the embodiments herein.

In some embodiments, there may be a user interface associated with system controller 829. The user interface may include a display screen, graphical software displays of the apparatus and/or process conditions, and user input devices such as pointing devices, keyboards, touch screens, microphones, etc.

In some embodiments, parameters adjusted by system controller 829 may relate to process conditions. Non-limiting examples include process gas composition and flow rates, temperature, pressure, plasma conditions (such as RF bias power levels), etc. These parameters may be provided to the user in the form of a recipe, which may be entered utilizing the user interface.

Signals for monitoring the process may be provided by analog and/or digital input connections of system controller 829 from various process tool sensors. The signals for controlling the process may be output on the analog and digital output connections of tool 800. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 829 may provide program instructions for implementing the above-

described deposition processes. The program instructions may control a variety of process parameters, such as DC power level, RF bias power level, pressure, temperature, etc. The instructions may control the parameters to operate in-situ deposition of film stacks according to various embodiments described herein.

The system controller 829 will typically include one or more memory devices and one or more processors configured to execute the instructions so that the apparatus will perform a method in accordance with disclosed embodiments. Machine-readable media containing instructions for controlling process operations in accordance with disclosed embodiments may be coupled to the system controller 829.

In some implementations, the system controller 829 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 829, depending on the processing conditions and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 829 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 829 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 829, in some implementations, may be a part of or coupled to a computer that is integrated with, coupled to the system, otherwise networked to the system, or a combination thereof. For example, the system controller 829 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the system controller 829 receives instructions in the form of data, which specify parameters for each of the processing steps to be performed during one or more operations. It should be understood that the parameters may be specific to the type of process to be performed and the type of tool that the system controller 829 is configured to interface with or control. Thus as described above, the system controller 829 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the system controller 829 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

An appropriate apparatus for performing the methods disclosed herein is further discussed and described in U.S. patents application Ser. Nos. 13/084,399 (now U.S. Pat. No. 8,728,956), filed Apr. 11, 2011, and titled “PLASMA ACTIVATED CONFORMAL FILM DEPOSITION”; and Ser. No. 13/084,305, filed Apr. 11, 2011, and titled “SILICON NITRIDE FILMS AND METHODS,” each of which is incorporated herein in its entireties.

The apparatus/process described herein may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility. Lithographic patterning of a film typically includes some or all of the following operations, each operation enabled with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

### Conclusion

Although the foregoing embodiments have been described in some detail for purposes of clarity of understanding, it will be apparent that certain changes and modifications may be practiced within the scope of the appended claims. Embodiments disclosed herein may be practiced without some or all of these specific details. In other instances, well-known process operations have not been described in detail to not unnecessarily obscure the disclosed embodiments. Further, while the disclosed embodiments will be described in conjunction with specific embodiments, it will be understood that the specific embodiments are not intended to limit the disclosed embodiments. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method, comprising:
receiving a substrate having features on a pedestal in a process chamber, wherein the process chamber comprises one or more chamber walls; and
depositing a silicon nitride film on the substrate using a non-plasma atomic layer deposition (ALD) process, wherein the pedestal is a temperature of at least about 400° C. during the non-plasma ALD process, and wherein the chamber walls are less than about 200° C. during the non-plasma ALD process.

2. The method of claim 1, wherein the non-plasma ALD process comprises one or more cycles of:
flowing a process gas comprising a silicon-containing precursor into the process chamber; and
after flowing the process gas, flowing a nitrogen-containing reactant into the process chamber.

3. The method of claim 2, wherein the silicon-containing precursor comprises a halogen group-containing silicon precursor.

4. The method of claim 2, wherein the silicon-containing precursor comprises dichlorosilane (DCS), hexachlorodisilane (HCDS), tetrachlorosilane, or any combination thereof.

5. The method of claim 2, wherein the nitrogen-containing reactant comprises ammonia (NH₃), hydrazine (N₂H₂), amines bearing carbon, or any combinations thereof.

6. The method of claim 2, further comprising flowing a hydrogen containing gas with the nitrogen-containing reactant.

7. The method of claim 2, wherein the non-plasma ALD process further comprises introducing a purge gas into the process chamber, wherein introducing the purge gas comprises:
1) introducing the purge gas after flowing the silicon-containing precursor;
2) introducing the purge gas after flowing the nitrogen-containing reactant; or both.

8. The method of claim 7, wherein a chamber pressure of the process chamber is reduced during the introducing the purge gas into the process chamber.

9. The method of claim 7, wherein the purge gas is flowed into the process chamber for a duration between about 0.1 seconds and about 10 seconds.

10. The method of claim 1, wherein during the non-plasma ALD process the pedestal temperature is at least about 600° C.

11. The method of claim 1, wherein the process chamber further comprises one or more thermal shields under the pedestal.

12. The method of claim 1, wherein the process chamber further comprises a showerhead, and during the non-plasma ALD process a temperature of the showerhead is less than about 170° C.

13. The method of claim 1, wherein silicon nitride does not substantially deposit on the chamber walls during the non-plasma ALD process.

14. The method of claim 1, wherein chamber pressure during the non-plasma ALD process is between about 5 Torr and about 50 Torr.

15. An apparatus for processing substrates, comprising:
a process chamber having one or more chamber walls and a pedestal;
a controller configured to control the process chamber for:
receiving a substrate having features on the pedestal in the process chamber;
depositing a silicon nitride film on the substrate using a non-plasma atomic layer deposition (ALD) process, wherein the pedestal is a temperature of at least about 400° C. during the non-plasma ALD process, and wherein the chamber walls are less than about 100° C. during the non-plasma ALD process.

16. The apparatus of claim 15, wherein the non-plasma ALD process comprises one or more cycles of:
flowing a process gas comprising a silicon-containing precursor into the process chamber; and
after flowing the process gas, flowing a nitrogen-containing reactant into the process chamber.

17. The apparatus of claim 15, wherein the process chamber further comprises one or more thermal shields under the pedestal.

18. The apparatus of claim 15, wherein silicon nitride does not substantially deposit on the chamber walls during the non-plasma ALD process.

19. An apparatus for processing substrates, the apparatus comprising:
one or more process chambers, each process chamber comprising a pedestal;
one or more inlet valves into the process chambers and associated flow-control hardware;
one or more oxygen filters, one or more moisture filters, or both fluidically connected with the one or more inlet valves; and
a controller configured to:
flow a silicon-containing precursor gas to the one or more process chambers;
flow a nitrogen-containing gas to form silicon nitride.

20. The apparatus of claim 19, wherein the one or more oxygen filters reduce a presence of oxygen below 1 part per billion (ppb) in the silicon-containing precursor gas, nitrogen-containing gas, or both.

21. The apparatus of claim 19, wherein the one or more moisture filters reduce a presence of water below 1 part per billion (ppb) in the silicon-containing precursor, nitrogen-containing gas, or both.

22. The apparatus of claim 19, wherein the controller is further configured to increase the temperature of the pedestal to at least about 500° C.

23. A method for processing substrates, the method comprising:
receiving a substrate having features on a pedestal in a process chamber,
filtering a process gas comprising a silicon-containing precursor to reduce the presence of at least one of oxygen and water below 1 part per billion;
filtering a nitrogen-containing gas to reduce the presence of oxygen, water, or both below 1 part per billion;
depositing a silicon nitride film on the substrate using a non-plasma atomic layer deposition (ALD) process, wherein the non-plasma ALD process comprises one or more cycles of:
flowing the process gas into the process chamber; and
after flowing the process gas, flowing a nitrogen-containing reactant into the process chamber.

24. The method of claim 23, wherein a temperature of the pedestal is at least about 500° C. during the non-plasma ALD process.
